(19) United States
(12) Patent Application Publication
(10) Pub. No.: US 2026/0068159 A1
(43) Pub. Date: Mar. 5, 2026

(54) SEMICONDUCTOR DEVICE

(71) Applicant: Kioxia Corporation, Tokyo (JP)

(72) Inventors: Mitsuo IKEDA, Yokkaichi Mie (JP); Daisuke IKENO, Yokkaichi Mie (JP)

(73) Assignee: Kioxia Corporation, Tokyo (JP)

(21) Appl. No.: 19/055,608

(22) Filed: Feb. 18, 2025

(30) Foreign Application Priority Data
Sep. 2, 2024 (JP) 2024-150731

(51) Int. Cl. H10B 43/27

(52) U.S. Cl. CPC H10B 43/27

(57) ABSTRACT

A first insulator and the second insulator are arranged with a distance therebetween in a first direction. A memory pillar extends in the first direction and penetrates the first and second insulators. A third insulator extends over a surface of the first insulator, a surface of the second insulator, and a first portion of a surface of the memory pillar. The first portion is located between the first and second insulators. Dot structures are on a surface of the third insulator. Each of the dot structures includes a metallic element or a carbon element. A first conductor extends over a surface of the third insulator and surfaces of the dot structures. A second conductor is on a surface of the first conductor, and includes molybdenum.

### CROSS-REFERENCE TO RELATED APPLICATION

This application is based upon and claims the benefit of priority from prior Japanese Patent Application No. 2024-150731, filed Sep. 2, 2024, the entire contents of which are incorporated herein by reference.

### FIELD

Embodiments described herein relate generally to a semiconductor device.

### BACKGROUND

There is known a memory device in which memory cells are three-dimensionally arranged. The memory device can include a film of a material that is different from a material in conventional art, in order to improve performance.

### BRIEF DESCRIPTION OF THE DRAWINGS

FIG. 1 illustrates an example of components and coupling of the components of a semiconductor device of a first embodiment.

FIG. 2 illustrates components and coupling of the components of a single block of the semiconductor device according to the first embodiment.

FIG. 3 illustrates a cross-sectional structure of a part of a memory cell array of the semiconductor device according to the first embodiment.

FIG. 4 schematically illustrates an example of a cross-sectional structure of a memory pillar of the semiconductor device according to the first embodiment.

FIG. 5 schematically illustrates an example of a cross-sectional structure of a part of an interconnect structure of the semiconductor device according to the first embodiment.

FIG. 6 to FIG. 13 schematically illustrate an example of states during manufacturing steps of the semiconductor device according to the first embodiment.

FIG. 14 illustrates a relationship between a temperature during deposition of molybdenum nitride and strength of deposited molybdenum.

### DETAILED DESCRIPTION

In general, according to one embodiment, a semiconductor device includes a first insulator, a second insulator, a memory pillar, a third insulator, a plurality of dot structures, a first conductor, and a second conductor. The first insulator and the second insulator are arranged with a distance therebetween in a first direction. The memory pillar extends in the first direction and penetrates the first insulator and the second insulator. The third insulator extends over a surface of the first insulator, a surface of the second insulator, and a first portion of a surface of the memory pillar. The first portion is located between the first insulator and the second insulator. The dot structures are on a surface of the third insulator. Each of the dot structures includes a metallic element or a carbon element. The first conductor extends over a surface of the third insulator and surfaces of the dot structures. The second conductor is on a surface of the first conductor, and includes molybdenum.

Embodiments will now be described with reference to the figures. In order to distinguish components having substantially the same function and configuration in an embodiment or over different embodiments from each other, an additional numeral or letter may be added to the end of each reference numeral or letter.

The figures are schematic, and the relation between the thickness and the area of a plane of a layer and the ratio of thicknesses of layers may differ from those in actuality. The figures may include components which differ in relations and/or ratios of dimensions in different figures.

The specification and the claims, when mentioning that a particular (first) component is “coupled” to another (second) component, intend to cover both the form of the first component directly coupled to the second component and the form of the first component coupled to the second component via one or more components which are always or selectively conductive.

Embodiments will be described using a three-dimensional orthogonal coordinate system. An x-axis extends in a X-direction. A y-axis extends in a Y-Direction. direction. A z-axis extends in a Z-direction.

### 1. First Embodiment

As an example of the semiconductor device, a storage device is described below. Examples of other semiconductor devices include a semiconductor device including an integrated circuit that includes a logic circuit.

### 1.1. Configuration (Structure)

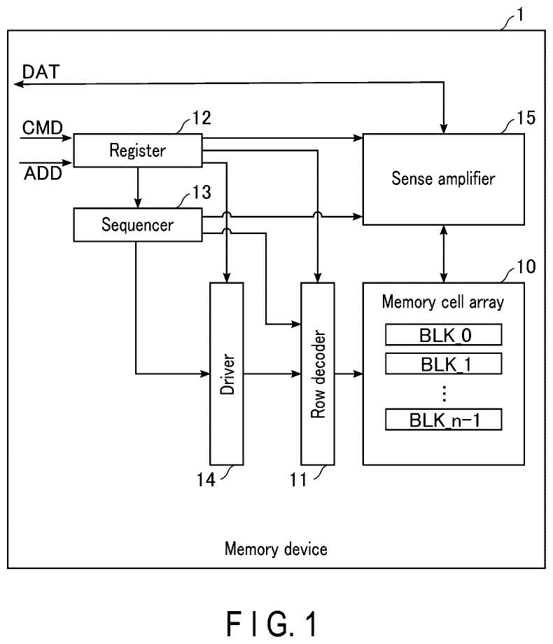

FIG. 1 illustrates an example of components and coupling of the components of a memory device according to a first embodiment. A memory device 1 is a device that stores data using memory cells. The memory device 1 operates based on a command CMD and address information ADD received from outside, or, in one example, a memory controller. The memory device 1 receives data DAT to be written, and outputs data stored in the memory device 1. In one example, the memory device is configured as a single semiconductor chip

As illustrated in FIG. 1, the memory device 1 includes components such as a memory cell array 10, a row decoder 11, a register 12, a sequencer 13, a driver 14, and a sense amplifier 15.

The memory cell array 10 is a set of arrayed memory cells. The memory cell array 10 includes a plurality of memory blocks (or blocks) BLK (BLK_0, BLK_1, . . . ). Each block BLK includes a plurality of memory cell transistors MT (not shown). In an area where the memory cell array 10 is provided, interconnects such as word lines WL (not shown) and bit lines BL (not shown) are also disposed.

The row decoder 11 is a circuit for selecting a block BLK. The row decoder 11 transfers a voltage supplied from the driver 14 to a single block BLK selected based on a block address received from the register 12.

The register 12 is a circuit that holds the command CMD and the address information ADD received by the memory device 1. The command CMD instructs the sequencer 13 to perform various operations including data read, data write, and data erasure. The address information ADD designates an access target in the memory cell array 10.

The sequencer 13 is a circuit that controls the entire operation of the memory device 1. The sequencer 13 controls the row decoder 11, the driver 14, and the sense amplifier 15 based on the command CMD received from the register 12 to perform various operations including data read, data write, and data erasure.

The driver 14 is a circuit that generates voltages of different magnitudes and applies the generated voltages to some of the components. The driver 14 supplies voltages among the generated voltages selected based on control by the sequencer 13 and the address information ADD to the row decoders 11.

The sense amplifier 15 is a circuit that outputs a signal based on data stored in the memory cell array 10. The sense amplifier 15 senses a state of the memory cell transistors MT, and generates read data based on the sensed state. The sense amplifier 17 transfers write data to the memory cell transistors MT.

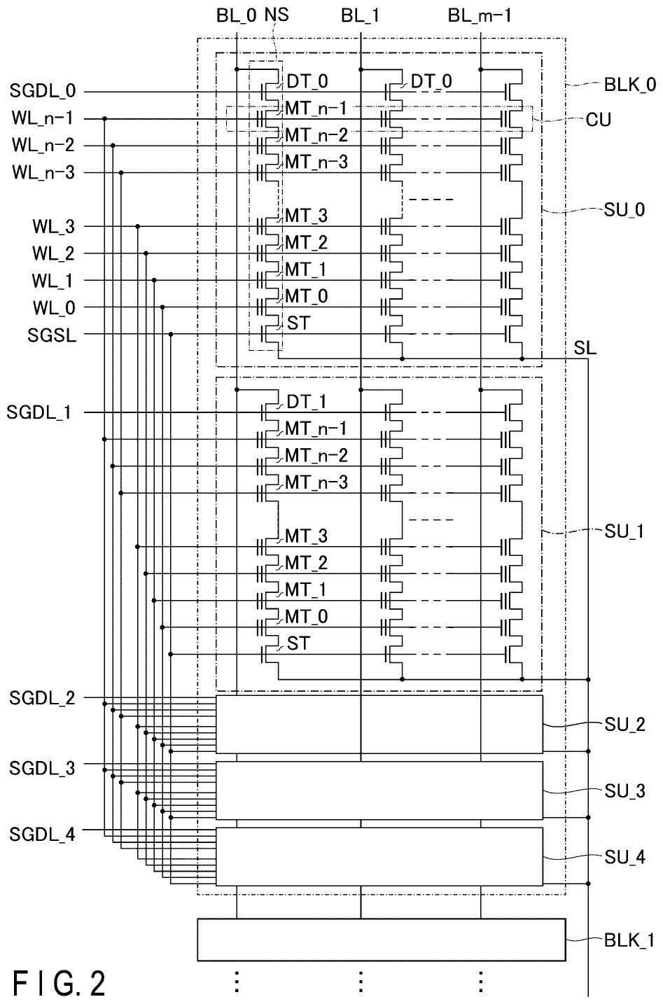

FIG. 2 illustrates components and coupling of the components of a single block of the semiconductor device according to the first embodiment. A plurality of blocks BLK, or, in one example, all blocks BLK, include the components and the coupling illustrated in FIG. 2.

A single block BLK includes a plurality of string units SU. FIG. 2 illustrates an example of five string units SU_0 to SU_4.

As illustrated in FIG. 2, each of m bit lines BL_0 to BL_m-1 is coupled, in each block BLK, to a single NAND string NS from each of string units SU_0 to SU_4, where m is a positive integer.

Each NAND string NS includes a single select gate transistor ST, n memory cell transistors MT (MT_0 to MT_n-1), and a single select gate transistor DT (DT_0, DT_1, DT_2, DT_3, or DT_4), where n is a positive integer. The memory cell transistor MT is an element that includes a control gate electrode and a charge accumulation film insulated from the surroundings and stores data in a nonvolatile manner based on charge in the charge accumulation film. The select gate transistors ST, memory cell transistors MT, and select gate transistor DT are coupled in series in the named order between a source line SL and a single bit line BL.

A plurality of NAND strings NS respectively coupled to a plurality of different bit lines BL constitute a single string unit SU. In each string unit SU, the control gate electrodes of the memory cell transistors MT_0 to MT_n-1 are coupled to the word lines WL_0 to WL_n-1, respectively. A set of memory cell transistors MT which share a single word line WL in one string unit SU is referred to as a “cell unit CU”.

The select gate transistors DT_0 to DT_4 belong to the string units SU_0 to SU_4, respectively. In FIG. 2, the select gate transistors DT_2, DT_3, and DT_4 are not illustrated. The gate of the select gate transistor DT_0 of each of the NAND strings NS of the string unit SU_0 is coupled to a select gate line SGDL_0. Similarly, the gates of the select gate transistors DT_1, DT_2, DT_3, and DT_4 of the respective NAND strings NS of the string units SU_1, SU_2, SU_3, and SU_4 are coupled to select gate lines SGDL_1, SGDL_2, SGDL_3, and SGDL_4.

The gate of the select gate transistor ST is coupled to a select gate line SGSL.

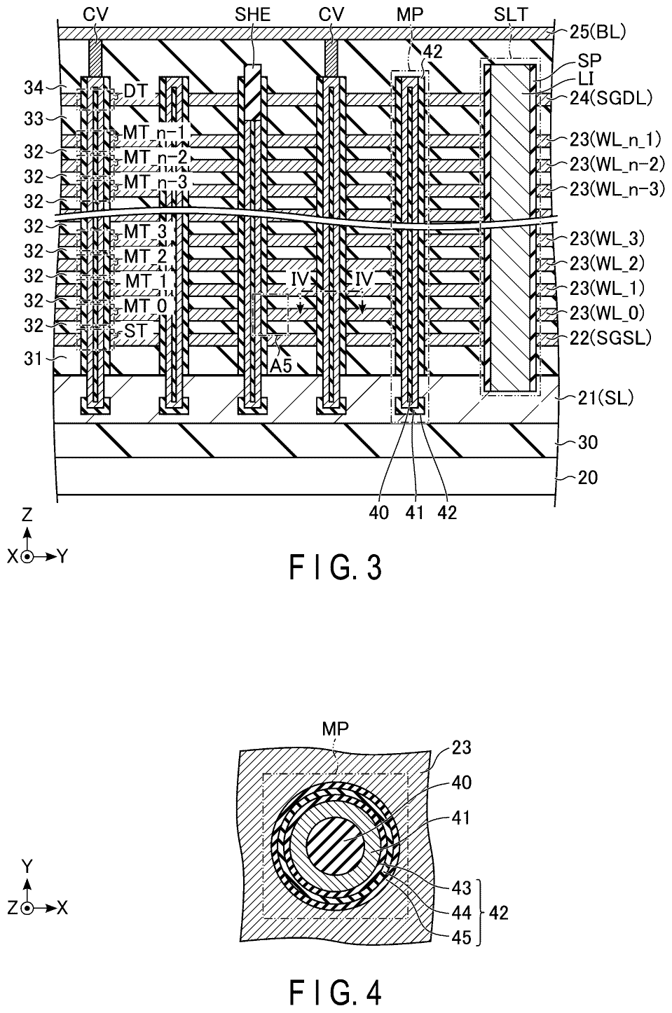

FIG. 3 illustrates a structure of a cross section of part of the memory cell array of the semiconductor device of the first embodiment, and illustrates a structure along a yz-plane.

As illustrated in FIG. 3, the memory cell array 10 includes a substrate 20, conductors 21, an interconnect structure 22, n interconnect structures 23, an interconnect structure 24, a conductor 25, and insulators 30 to 34. In one example, the insulators 30 to 34 include or are substantially made of silicon oxide. The description “substantially made of” is meant to permit a component “substantially made of” something to contain unintended impurities.

The substrate 20 is a substrate of semiconductor. In one example, the substrate 20 includes or is substantially made of p-type silicon.

The insulator 30 is located on a surface (upper surface) of the substrate on a side of Z-direction.

The conductor 21 is located on an upper surface of the insulator 30. The conductor 21 extends along an xy-plane, and has a plate shape. The conductor 21 functions as at least part of the source line SL. In one example, the conductor 21 includes or is substantially made of silicon doped with phosphorus.

The insulator 31 is located on an upper surface of the conductor 21.

The interconnect structure 22 is located on an upper surface of the insulator 31. The interconnect structure 22 extends along the xy-plane, and has a plate shape. In one example, the interconnect structure 22 includes molybdenum or a conductor substantially made of molybdenum. The interconnect structure 22 functions as at least part of the select gate line SGSL.

The insulators 32 and the interconnect structures 23 are located alternately one by one in the Z-direction on an upper surface of the interconnect structure 22. Accordingly, the interconnect structures 23 are arranged in the Z-direction spaced from each other or at intervals. The insulators 32 and the interconnect structures 23 extend along the xy-plane, and have a plate shape. The interconnect structure 23 includes a conductor. The interconnect structure 23 will be described in detail later. The interconnect structures 23 in order from a side of the substrate 20 respectively function as at least part of the word lines WL_0 to WL_n-1.

The insulator 33 is located on an upper surface of an uppermost interconnect structure 23.

The interconnect structure 24 is located on an upper surface of the insulator 33. The conductor 24 extends along the xy-plane, and has a plate shape. The interconnect structure 24 includes a conductor. In one example, the interconnect structure 24 includes molybdenum or a conductor substantially made of molybdenum. The interconnect structure 24 functions as at least part of the select gate line SGDL.

The insulator 34 is located on an upper surface of the interconnect structure 24.

The conductor 25 is located on an upper surface of the insulator 34. The conductor 25 has a linear shape, and extends in the Y-direction. The conductor 25 functions as at least part of a single bit line BL. The conductors 25 are also provided on yz-planes that are different from the yz-plane shown in FIG. 3, and therefore the conductors 25 are arranged in the X-direction at intervals. In one example, the conductor 25 includes or is substantially made of copper.

The memory pillars MP extend in the Z-direction, and has a pillar shape. The memory pillar MP is located in a layer stack including the insulators 31 to 34 and the interconnect structures 22 to 24, and penetrates or passes through the insulators 31 to 34 and the interconnect structures 22 to 24. An upper surface of the memory pillar MP is located farther in the Z-direction than the interconnect structure 24. A lower surface of the memory pillar MP is located in the conductor 21. A portion where the memory pillar MP and the interconnect structure 22 are in contact with each other functions as the select gate transistor ST. A portion where the memory pillar MP and a single interconnect structure 23 are in contact with each other functions as a single memory cell transistor MT. A portion where the memory pillar MP and the interconnect structure 24 are in contact with each other functions as the select gate transistor DT.

The memory pillar MP includes a core 40, a semiconductor 41, and a layer stack 42. The core 40 is substantially made of an insulator, and, in one example, includes or is substantially made of silicon oxide. The core 40 extends in the Z-direction, and has a pillar shape. In one example, the semiconductor 41 includes or is substantially made of silicon. The semiconductor 41 covers a surface of the core 40. The layer stack 42 covers a side surface and a lower surface of the semiconductor 41. The layer stack 42 has an opening in the conductor 21, and the conductor 21 is partially located in the opening. In the opening, the conductor 21 is in contact with the semiconductor 41.

Each memory pillar MP is coupled to a single conductor 25 by the contact plug CV.

The member SLT extends along an xz-plane, and divides the interconnect structures 22 to 24. An upper surface of the member SLT is located above the upper surfaces of the memory pillars MP. The member SLT includes a conductor LI and a spacer SP. A lower surface of the contact LI is in contact with the conductor 21. The spacer SP is located between the contact LI and the set of the interconnect structures 22 to 24, and insulates the contact LI from the interconnect structures 22 to 24. The contact LI functions as part of the source line SL.

The member SHE extends along the xz-plane, extends in the Z-direction, and divides the interconnect structure 24. A lower surface of the member SHE is located in the insulator 33. In one example, the member SHE includes or is substantially made of silicon oxide.

FIG. 4 illustrates an example of a structure of a cross section of a memory pillar of the semiconductor device according to the first embodiment. Specifically, FIG. 4 illustrates a cross section along line IV-IV of FIG. 3. As illustrated in FIG. 4, the layer stack 42 includes a tunnel insulator 43, a charge storage film 44, and a block insulator 45.

The tunnel insulator 43 surrounds the side surface of the semiconductor 41. The charge storage film 44 surrounds a side surface of the tunnel insulator 43. The block insulator 45 surrounds a side surface of the charge storage film 44. The conductor 23 surrounds a side surface of the block insulator 45.

The semiconductor 41 functions as a channel (or, a current path) of the memory cell transistors MT and the select gate transistors DT and ST. In one example, each of the tunnel insulator 43 and the block insulator 45 includes or is substantially made of silicon oxide. The charge storage film 44 stores charges. In one example, the charge storage film 44 includes or is substantially made or silicon nitride.

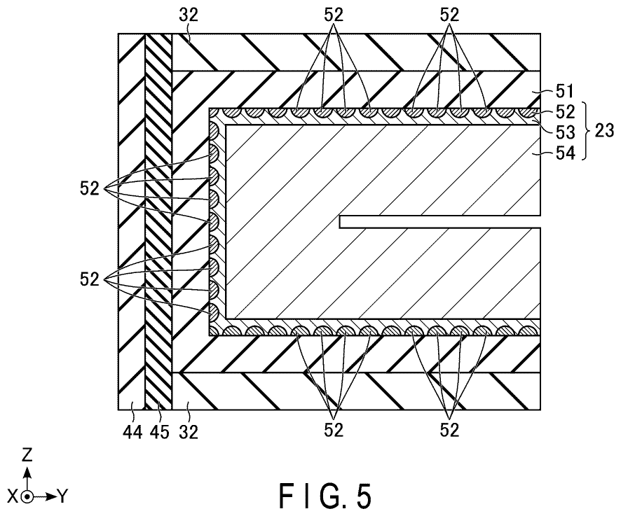

FIG. 5 schematically illustrates an example of a cross-sectional structure of a part of the interconnect structure of the semiconductor device according to the first embodiment. FIG. 5 illustrates a region A5 in FIG. 3, and illustrates a region of a boundary between a single interconnect structure 23 and a memory pillar MP.

As illustrated in FIG. 5, the memory device 1 further includes an insulator 51, and the interconnect structure 23 includes dot structures 52, and conductors 53 and 54.

The insulator 51 has a film shape. The insulator 51 surrounds a surface of the interconnect structure 23. Specifically, the insulator 51 covers an upper surface of the insulator 32 located in the −Z direction between two insulators 32 arranged in the Z-direction. The insulator 51 covers a −Z directional-side surface of the insulator 32 located in the Z direction between the two insulators 32 arranged in the Z-direction. The insulator 51 covers that part of the surface of the block insulator 45, which is located between the two insulators 32 arranged in the Z-direction. In one example, the insulator 51 includes or is substantially made of aluminum oxide.

The dot structures 52 are located on a surface of the insulator 51. The dot structure 52 is an agglomerate of elements included in the dot structure 52, and has an irregular shape. The dot structures 52 are irregularly distributed. A set of dot structures 52 are discretely distributed, and covers a major part of the surface of the insulator 51. On the other hand, the dot structures 52 do not have a layer shape, and do not need to cover the entirety of the insulator 51. Thus, the dot structures 52 include a pair of dot structures 52 having a distance therebetween. In the Z-direction of the dot structure 52, for example, the height in the Z-direction of the dot structure 52 is 1 nm or less.

In one example, the dot structure 52 includes a metallic element or carbon (C). In a more specific example, the dot structure 52 includes aluminum (Al), zirconium (Zr), niobium (Nb), hafnium (Hf), titanium (Ti), chromium (Cr), and carbon. The aluminum, zirconium, niobium, hafnium and titanium are metals having a lower ionization energy than the ionization energy of molybdenum. In another example, the dot structure 52 includes nitrides of metals, and include nitrides of aluminum, zirconium, niobium, hafnium, titanium and chromium.

In one example, a surface density of metallic elements of the dot structure 52 is 1×10¹³ [atoms/cm²] or more, and 1×10¹⁵ [atoms/cm²] or less.

The conductor 53 is located on that part of the surface of the insulator 51, which is not covered by the dot structures 52, and is located on the surfaces of the dot structures 52. The conductor 53 covers that part of the surface of the insulator 51, which is not covered by the dot structures 52, and covers the surfaces of the dot structures 52. In other words, the conductor 53 includes the dot structures 52 therein, and the surface of the insulator 51 is covered by the set of the conductor 53 and the dot structures 52. In one example, the conductor 53 includes or is substantially made of molybdenum nitride.

The conductor 54 covers a surface of the conductor 53, and is buried in an almost entire region surrounded by the conductor 53. In other words, the conductor 54 is buried in an almost entire region in the interconnect structure 23, in which the dot structures 52 and conductor 53 are not provided. The conductor 54 may be buried in the entire region surrounded by the conductor 53. In one example, the conductor 54 includes or is substantially made of molybdenum.

Each of the interconnect structures 22 and 24 can include the same configuration as the interconnect structure 23, that is, can include the dot structures 52 and the conductors 53 and 54.

### 1.2. Manufacturing Method

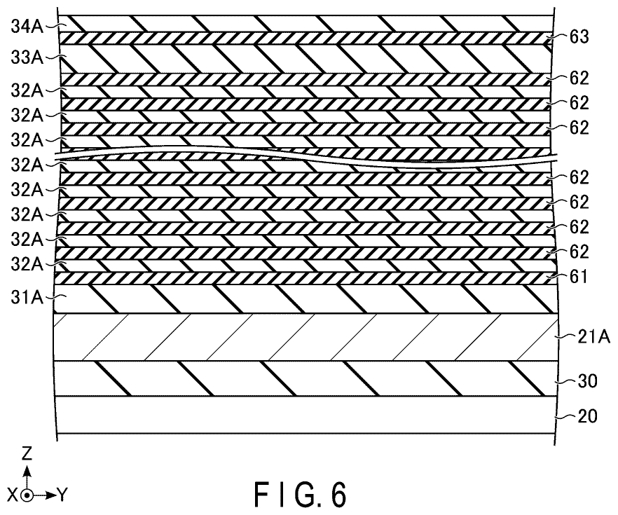

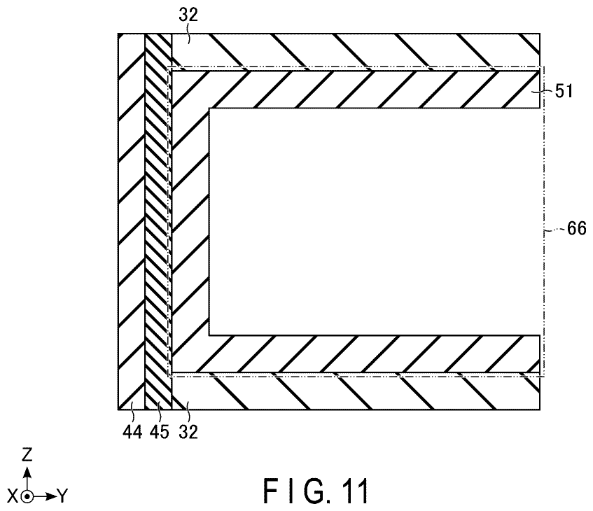

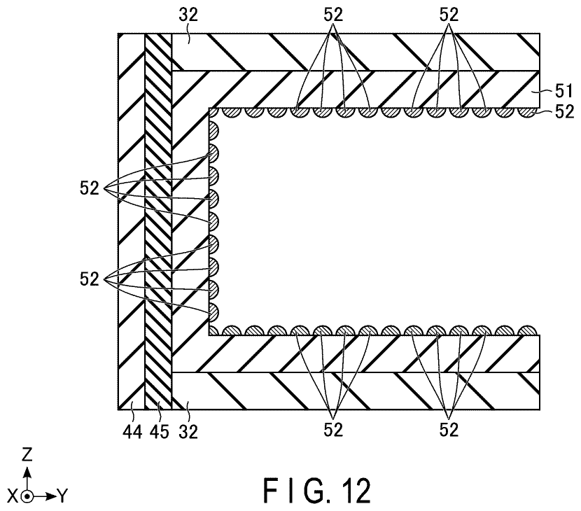

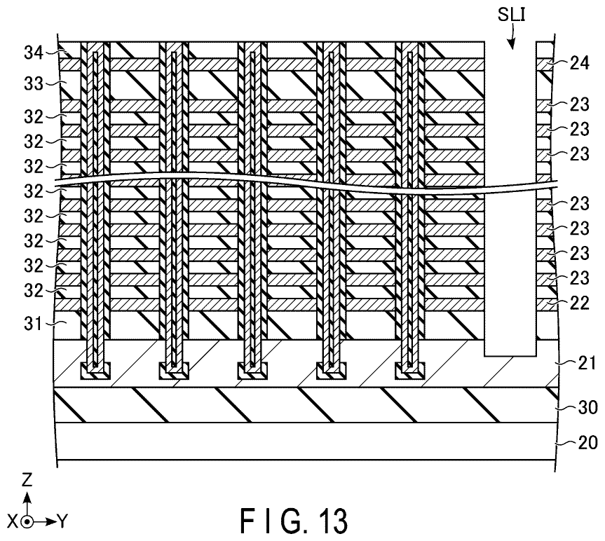

FIG. 6 to FIG. 13 schematically illustrate an example of states during manufacturing steps of the semiconductor device according to the first embodiment. FIG. 6 to FIG. 10, and FIG. 13 illustrate the same region as the region illustrated in FIG. 3. FIG. 11 and FIG. 12 illustrate the same region as the region illustrated in FIG. 5.

As illustrated in FIG. 6, an insulator 30, a conductor 21A, and insulators 31A, 61, 32A, 62, 33A, 63 and 34A are deposited on an upper surface of a substrate 20. Specifically, at first, the insulator 30, conductor 21A, and insulators 31A and 61 are deposited on the upper surface of the substrate 20. The conductor 21A occupies a layer of a region where the conductor 21 is to be formed. The insulator 31A occupies a layer of a region where the insulator 31 is to be formed. The insulator 31A is substantially formed of a material of the insulator 31. The insulator 61 occupies a layer of a region where the interconnect structure 22 is to be formed. In one example, the insulator 61 includes or is substantially made of silicon nitride. Examples of the method of deposition of the insulator 30, conductor 21A, and insulators 31A and 61 include chemical vapor deposition (CVD).

The insulators 32A and the insulators 62 are alternately deposited one by one on an upper surface of the insulator 61. Each insulator 62 occupies a layer of a region where a single interconnect structure 23 is to be formed. In one example, the insulator 62 includes or is substantially made of silicon nitride. Examples of the method of deposition of the insulator 32A and insulators 62 include CVD.

The insulators 33A, 63 and 34A are deposited on an upper surface of the uppermost insulator 62. The insulator 33A occupies a layer of a region where the insulator 33 is to be formed. The insulator 33A is substantially made of a material of the insulator 33. The insulator 63 occupies a layer of a region where the interconnect structure 24 is to be formed. In one example, the insulator 63 includes or is substantially made of silicon nitride. The insulator 34A constitutes a part of the insulator 34. Examples of the method of deposition of the insulators 33A, 63 and 34A include CVD.

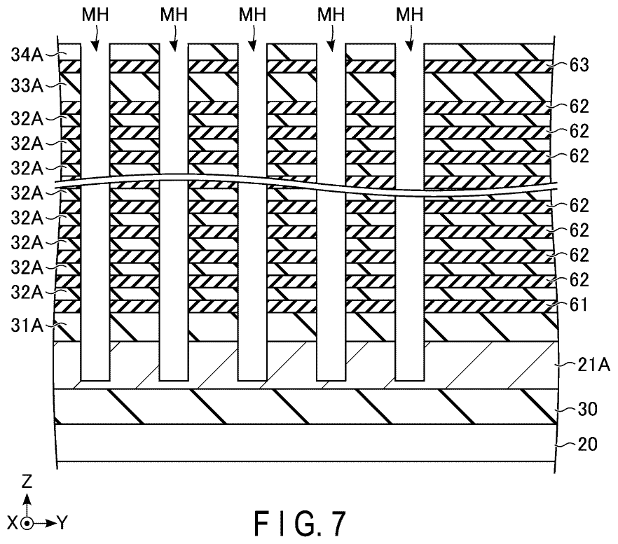

As illustrated in FIG. 7, memory holes MH are formed. The memory holes MH occupy regions where the memory pillars MP are to be formed, and reach the conductor 21A through the insulators 31A, 61, 32A, 62, 33A, 63 and 34A. Examples of the method of forming the memory holes MH include a set of a photolithography step and anisotropic etching such as reactive ion etching (RIE).

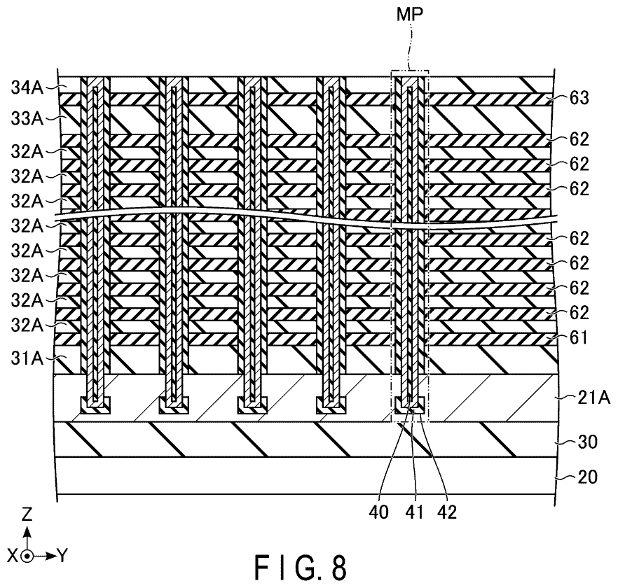

As illustrated in FIG. 8, memory pillars MP are formed. Specifically, at first, a layer stack 42, that is, a block insulator 45, a tunnel insulator 43 and a charge storage film 44, is deposited on a surface of the memory hole MH. Examples of the method of deposition of the layer stack 42 include CVD.

A part of the layer stack 42 which is located in the conductor 21A is removed. A semiconductor 41 is deposited on a surface of the layer stack 42. Examples of the method of deposition include CVD.

By a core 40 being deposited on a surface of the semiconductor 41, the center of the memory hole MH is filled with the core 40. Examples of the method of deposition include CVD. Thereafter, an upper portion of the core 40 is removed, and a semiconductor 41 is formed on a part from which the upper portion of the core 40 has been removed. Thus, the memory pillars MP are formed.

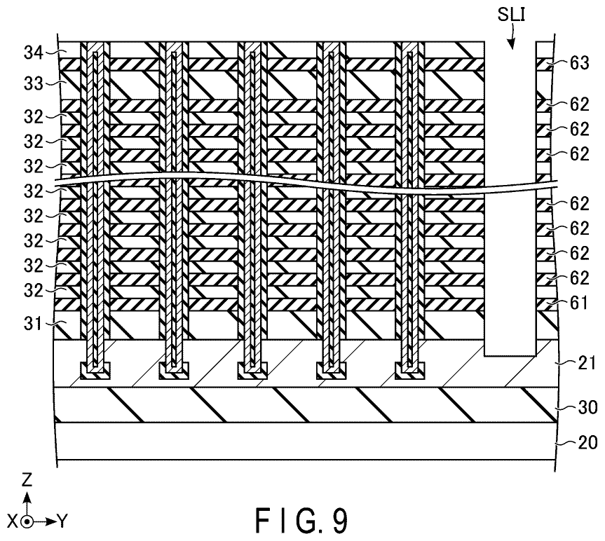

As illustrated in FIG. 9, a slit SLI is formed. The slit SLI occupies a region where the member SLT is to be formed. The slit SLI penetrates the conductor 21A, and the insulators 31A, 61, 32A, 62, 33A, 63 and 34A. By the formation of the slit SLI, the insulators 31A, 32A and 33A and the conductor 21A become the insulators 31, 32 and 33 and the conductor 21, respectively. Examples of the method of forming the slit SLI include a set of a photolithography step and anisotropic etching such as RIE.

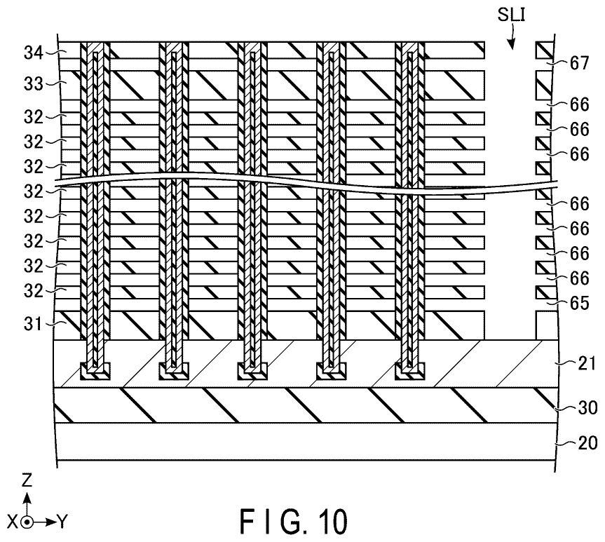

As illustrated in FIG. 10, the insulators 61, 62 and 63 are removed. Examples of the method of removing include wet etching. As a chemical solution for wet etching, use is made of a chemical solution having a selectivity to the set of the insulators 61, 62 and 63 and the set of the insulators 31, 32, 33 and 34. The chemical solution reaches the insulators 61, 62 and 63 from the slit SLI, and removes the insulators 61, 62 and 63. By the removal, spaces 65, 66 and 67 are formed in the regions where the insulators 61, 62 and 63 were located, respectively.

As illustrated in FIG. 11, an insulator 51 is deposited on surfaces of each space 66, that is, an upper surface of the insulator 32 located in the −Z direction between two insulators 32 arranged in the Z-direction, a lower surface of the insulator 32 located in the Z direction between the two insulators 32 arranged in the Z-direction, and that part of the surface of the block insulator 45, which is located between the two insulators 32 arranged in the Z-direction. Examples of the method of deposition include CVD. The insulator 51 can also be deposited on surfaces of the spaces 65 and 67.

As illustrated in FIG. 12, dot structures 52 are formed on a surface of the insulator 51. Examples of the method of formation include an atomic layer deposition (ALD). The dot structures 52 can also be formed on surfaces of the insulators 51 in the spaces 65 and 67.

As illustrated in FIG. 5 and FIG. 13, interconnect structures 23 are formed. Specifically, the conductor 53 is deposited on surfaces of the insulator 51 and dot structures 52. Examples of the method of deposition include ALD. Examples of the material used in the ALD include MoO₂Cl₂. In one example, the flow temperature of ALD is 300° C. or above.

A conductor 54 is deposited on a surface of the conductor 53. Examples of the method of deposition include CVD. The conductor 53 can function as a seed layer during the formation of the conductor 54.

As illustrated in FIG. 3, the spacer SP, conductor LI and insulator SHE are formed. Then, the remaining portion of the insulator 34, contact plug CV and conductor 25 are formed, and thereby the structure illustrated in FIG. 3 is obtained.

### 1.3. Advantages (Advantageous Effects)

According to the first embodiment, as described below, a memory device is realized which includes memory cell transistors in which deterioration in characteristics is suppressed, and includes conductors with high strength. In order to preferably form the conductor 54 of molybdenum, a film of molybdenum nitride can be formed between the insulator 51 and the conductor 54. If the temperature (flow temperature) of MoO₂Cl₂ used as the material of the molybdenum nitride film is low, the impurities (oxygen and chloride) of the molybdenum nitride film are large. Oxygen in the molybdenum nitride film bonds to hydrogen in molybdenum that is deposited later, and functions as a defect at an interface between the insulator 51 and the block insulator 45. The defect captures electrons, and this leads to deterioration in characteristics of the memory cell transistor MT.

If the flow temperature of MoO₂Cl₂ is high, the impurities of the molybdenum nitride film are suppressed. However, as the flow temperature becomes higher, the MoO₂Cl₂ that is once adsorbed on the insulator 51 is more easily desorbed from the insulator 51. As a countermeasure, an incubation (i.e., cycle time) of ALD can be increased. However, this deteriorates the coverage of the molybdenum nitride film, and, specifically, the molybdenum nitride is formed not in a film layer, but in a shape of discretely distributed agglomerates. As a result, the coverage of the conductor 54 is poor, and the strength of the conductor 54 is low. In this manner, the use of the molybdenum nitride makes it difficult to compatibly achieve the suppression of deterioration in characteristics of the memory cell transistor MT and the securing of strength of the conductor 54.

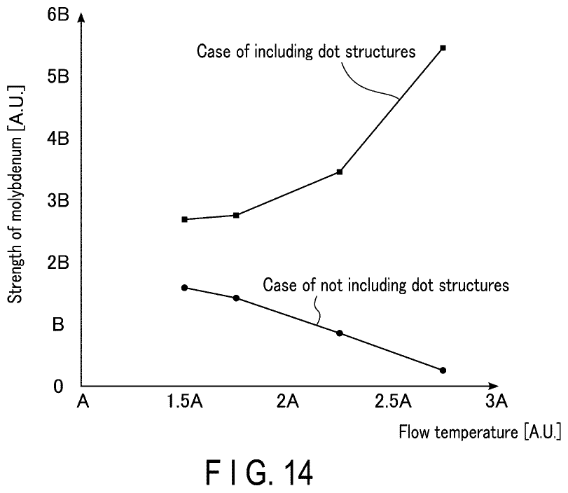

According to the first embodiment, the interconnect structure 23 includes the dot structures 52 on the surface of the insulator 51, and the conductor 53 on the surfaces of the insulator 51 and dot structures 52. The dot structures 52 suppresses desorption of the molybdenum nitride that was once deposited at high flow temperatures. It is thus possible to suppress deterioration in characteristics of the memory cell transistor MT by the deposition at high flow temperatures, and to form the conductor 53 with high strength. FIG. 14 illustrates a result of an experiment relating to the relationship between flow temperatures in a case where molybdenum nitride is deposited on aluminum oxide, and the strength of molybdenum deposited on the molybdenum nitride. In FIG. 14, a freely selected unit (A.U.) is used. FIG. 14 illustrates a case where molybdenum nitride is directly deposited on aluminum oxide, and a case where molybdenum nitride is deposited on aluminum oxide (51) and dot structures (52), as in the first embodiment. As illustrated in FIG. 14 and as described above, in the case where the molybdenum nitride is deposited on the aluminum oxide, the strength of the film of the deposited molybdenum becomes lower as the flow temperature of the material of the molybdenum nitride is higher. On the other hand, in the case where the molybdenum nitride is deposited on the aluminum oxide by using the dot structures, the strength of the film of the molybdenum becomes higher as the flow temperature of the material is higher.

According to the first embodiment, since the conductor 53 can be deposited by using the material at high flow temperatures (300° C. or above), the concentration of oxygen at the interface between the insulator 51 and the block insulator 45 is low. To be more specific, the concentration of oxygen at the interface between the insulator 51 and the block insulator 45 is 5×10¹⁸ [atoms/cm³] or more, and 5×10²⁰ [atoms/cm³] or less. This concentration of oxygen is lower than the concentration of oxygen in the above-described case where the molybdenum nitride is deposited at low temperatures, and the deterioration in characteristics of the memory cell transistor MT is suppressed.

According to the first embodiment, the dot structures 52, which are not in a film shape, are provided between the insulator 51 and the conductor 53. Because of the shape of the dot structures 52, the dot structures 52 do not need to have such a thickness as in the case where the material of dot structures 52 is formed in a film shape. In general, in order for a material to have a shape of a film, the material needs to have a thickness of 1 nm or more, whereas the dot structures 52 can be formed with a height of 1 nm or less. As a result, the ratio of the volume of the dot structures 52 in the volume of the interconnect structure 23 is low. Therefore, an increase in resistance of the interconnect structure 23 by the dot structures 52 can be suppressed, and the interconnect structure 23 having low resistance can be realized.

### 1.4. Modification

As described above, the conductor 53 can function as a seed layer during the formation of the conductor 54. For this purpose, the conductor 53 can cover the dot structures 52. However, in a case where the conductor 54 can be formed without using the conductor 53 as the seed layer, the conductor 53 does not need to cover the dot structures 52. In this case, the thickness of the conductor 53 is less than the height of the dot structures 52, and some dot structures 52 are exposed from the surface of the conductor 53.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first insulator and a second insulator that are arranged with a distance therebetween in a first direction;
a memory pillar extending in the first direction and penetrating the first insulator and the second insulator;
a third insulator extending over a surface of the first insulator, a surface of the second insulator, and a first portion of a surface of the memory pillar, the first portion being located between the first insulator and the second insulator;
a plurality of dot structures on a surface of the third insulator, each of the dot structures including a metallic element or a carbon element;
a first conductor extending over a surface of the third insulator and surfaces of the dot structures; and
a second conductor on a surface of the first conductor, the second conductor including molybdenum.

2. The semiconductor device of claim 1, wherein each of the dot structures includes a metal nitride.

3. The semiconductor device of claim 1, wherein each of the dot structures includes aluminum, zirconium, niobium, hafnium, or titanium.

4. The semiconductor device of claim 1, wherein each of the dot structures includes a nitride of aluminum, zirconium, niobium, hafnium, or titanium.

5. The semiconductor device of claim 1, wherein a surface density of the metallic element is 1×10¹³ [atoms/cm²] or more, and 1×10¹⁵ [atoms/cm²] or less.

6. The semiconductor device of claim 1, wherein
the memory pillar includes a fourth insulator that is in contact with the third insulator, and
an oxygen concentration at a boundary between the third insulator and the fourth insulator is 5×10¹⁸ [atoms/cm³] or more, and 5×10²⁰ [atoms/cm³] or less.

7. The semiconductor device of claim 1, wherein the first conductor includes molybdenum nitride.

8. The semiconductor device of claim 7, wherein the third insulator includes aluminum oxide.

9. The semiconductor device of claim 2, wherein the first conductor includes molybdenum nitride.

10. The semiconductor device of claim 9, wherein the third insulator includes aluminum oxide.

11. The semiconductor device of claim 3, wherein the first conductor includes molybdenum nitride.

12. The semiconductor device of claim 11, wherein the third insulator includes aluminum oxide.

13. The semiconductor device of claim 4, wherein the first conductor includes molybdenum nitride.

14. The semiconductor device of claim 13, wherein the third insulator includes aluminum oxide.

15. The semiconductor device of claim 5, wherein the first conductor includes molybdenum nitride.

16. The semiconductor device of claim 15, wherein the third insulator includes aluminum oxide.
